(19) United States
(12) Patent Application Publication
(10) Pub. No.: US 2023/0207348 A1
(43) Pub. Date: Jun. 29, 2023

(54) HEAT TREATMENT APPARATUS

(71) Applicant: SCREEN Holdings Co., Ltd., Kyoto (JP)

(72) Inventors: Yukio ONO, Kyoto-shi, Kyoto (JP); Takahiro YAMADA, Kyoto-shi, Kyoto (JP); Makoto ABE, Kyoto-shi, Kyoto (JP)

(21) Appl. No.: 17/926,642

(22) PCT Filed: May 25, 2021
(86) PCT No.: PCT/JP2021/019761

§ 371 Date: Nov. 21, 2022

(30) Foreign Application Priority Data
May 29, 2020 (JP) 2020-094363

(51) Int. Cl. H01L 21/67; H01L 21/687

(52) U.S. Cl. CPC H01L 21/67115; H01L 21/6875; H01L 21/67248; H01L 21/68742; H01L 21/68785

(57) ABSTRACT

A plurality of substrate support pins are erected on a susceptor that holds a semiconductor wafer that is an object being treated. The plurality of substrate support pins are set in a ring shape at equal intervals. A flash lamp irradiates the semiconductor wafer supported by the plurality of substrate support pins with flash light to heat the semiconductor wafer. The radius of a setting circle in which the plurality of substrate support pins are set is made larger as the pulse width of flash light emitted from the flash lamp decreases. To irradiate the semiconductor wafer with flash light while having the semiconductor wafer supported by the plurality of substrate support pins can prevent cracking of the semiconductor wafer despite possible abrupt deformation of the semiconductor wafer due to the flash-light irradiation.

### TECHNICAL FIELD

The present invention relates to a heat treatment apparatus which irradiate a thin plate-like precision electronic substrate (hereinafter referred to simply as a “substrate”) such as a semiconductor wafer with a flash of light to heat the substrate.

### BACKGROUND ART

In the process of manufacturing a semiconductor device, attention has been given to flash lamp annealing (FLA) which heats a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

Such flash lamp annealing is used for processes that require heating in an extremely short time, e.g. typically for the activation of impurities implanted in a semiconductor wafer. The irradiation of the surface of the semiconductor wafer implanted with impurities by an ion implantation process with a flash of light emitted from the flash lamps allows the temperature rise in the surface of the semiconductor wafer to an activation temperature only for an extremely short time, thereby achieving only activation of the impurities without deep diffusion of the impurities.

In a heat treatment apparatus using a flash lamp, typically, as disclosed in Patent Documents 1 and 2, for example, a semiconductor wafer is irradiated with flash light by a flash lamp while being supported by a plurality of support pins erected on a susceptor.

### PRIOR ART DOCUMENTS

### Patent Documents

Patent Document 1: Japanese Patent Application Laid-Open No. 2009-164451
Patent Document 2: Japanese Patent Application Laid-Open No. 2014-157968

### SUMMARY

### Problem to Be Solved by the Invention

However, the flash lamp instantaneously irradiates the front surface of the semiconductor wafer with flash light having extremely high energy, and thus the temperature of the front surface of the semiconductor wafer rapidly increases in a moment. Meanwhile, the temperature of the back surface does not increase so much. For this reason, only the front surface of the semiconductor wafer thermally expands rapidly, so that the semiconductor wafer is deformed so as to warp in such a manner that its front surface becomes convex. As a result, particularly when the energy of flash light is enhanced, stress concentration occurs in the back surface of the semiconductor wafer, causing a problem of cracking of the semiconductor wafer.

The present invention has been made in view of the above problems, and an object of the present invention is to provide a heat treatment apparatus capable of preventing a substrate from being cracked also during flash-light irradiation.

### Means to Solve the Problem

To solve the above-described problems, according to a first aspect of the present invention, a heat treatment apparatus that irradiates a substrate with flash light to heat the substrate, includes: a chamber that accommodates the substrate; a susceptor that holds the substrate in the chamber; and a plurality of support pins provided on the susceptor to support the substrate; and a flash lamp that irradiates the substrate held by the susceptor with flash light, wherein positions where the plurality of support pins are set on the susceptor differ according to a pulse width of flash light emitted from the flash lamp.

According to a second aspect, in the heat treatment apparatus according to the first aspect, the plurality of support pins are set in a ring shape on the susceptor, and a radius of a setting circle in which the plurality of support pins are set increases as the pulse width decreases.

According to a third aspect, in the heat treatment apparatus according to the second aspect, when the pulse width is less than 0.8 milliseconds, the radius of the setting circle is larger than 93% of a radius of the substrate, when the pulse width is equal to or more than 0.8 milliseconds and is less than 5 milliseconds, the radius of the setting circle is larger than 83% of the radius of the substrate and is equal to or smaller than 93% of the radius of the substrate, when the pulse width is equal to or more than 5 milliseconds and is less than 10 milliseconds, the radius of the setting circle is larger than 77% of the radius of the substrate and is equal to or smaller than 83% of the radius of the substrate, when the pulse width is equal to or more than 10 milliseconds and is less than 20 milliseconds, the radius of the setting circle is larger than 73% of the radius of the substrate and is equal to or smaller than 77% of the radius of the substrate, and when the pulse width is equal to or more than 20 milliseconds, the radius of the setting circle is equal to or smaller than 73% of the radius of the substrate.

According to a fourth aspect, the heat treatment apparatus according to any one of the first to third aspects further includes a pin moving mechanism that changes the positions of the plurality of support pins in accordance with the pulse width.

According to a fifth aspect, in the heat treatment apparatus according to the fourth aspect, a plurality of slits are formed along a radial direction in the susceptor, and the pin moving mechanism slides the plurality of support pins along the plurality of slits.

### Effects of the Invention

With the heat treatment apparatus according to the first to fifth aspects, the setting positions of the plurality of support pins on the susceptor differ according to a pulse width of flash light emitted from the flash lamp. This can prevent cracking of the substrate despite possible abrupt deformation of the substrate during the flash-light irradiation.

### BRIEF DESCRIPTION OF THE DRAWINGS

FIG. 1 is a longitudinal sectional view showing a configuration of a heat treatment apparatus according to the present invention.

FIG. 2 is a perspective view showing the entire external appearance of a holder.

FIG. 3 is a plan view of a susceptor.

FIG. 4 is a sectional view of the susceptor.

FIG. 5 is a plan view of a transfer mechanism.

FIG. 6 is a side view of the transfer mechanism.

FIG. 7 is a plan view showing an arrangement of halogen lamps.

FIG. 8 is a view for explaining a pulse width of flash light emitted from flash lamps.

FIG. 9 is a view for explaining a setting circle in which substrate support pins are set.

FIG. 10 is a view showing a correlation between a pulse width and a radius of the setting circle, by which cracking of a semiconductor wafer can be reduced.

FIG. 11 is a view showing a correspondence between a pulse width and a radius of the setting circle.

FIG. 12 is a plan view of a susceptor according to a second embodiment.

FIG. 13 is a view showing a manner in which a substrate support pin is caused to slide over a slit of the susceptor.

### DESCRIPTION OF EMBODIMENTS

Below, embodiments of the present invention will be described in detail with reference to the drawings.

### First Embodiment

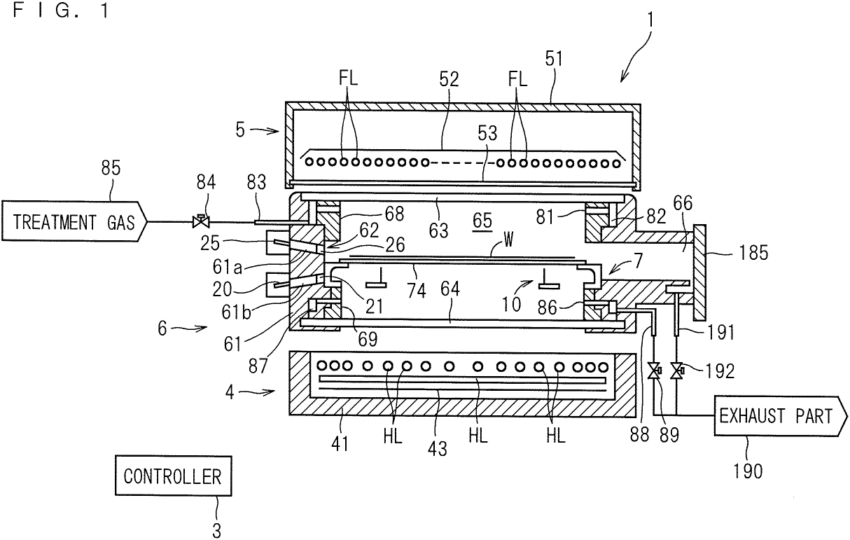

First, an overall configuration of a heat treatment apparatus according to the present invention will be described. FIG. 1 is a longitudinal sectional view showing a configuration of a heat treatment apparatus 1 according to the present invention. The heat treatment apparatus 1 of FIG. 1 is a flash lamp annealer for irradiating a disk-shaped semiconductor wafer W serving as a substrate with flashes of light to heat the semiconductor wafer W. The size of the semiconductor wafer W to be treated is not particularly limited. For example, the semiconductor wafer W to be treated has a diameter of 300 mm and 450 mm. It should be noted that the dimensions of components and the number of components are shown in exaggeration or in simplified form, as appropriate, in FIG. 1 and the subsequent figures for the sake of easier understanding.

The heat treatment apparatus 1 includes a chamber 6 for receiving a semiconductor wafer W therein, a flash heating part 5 including a plurality of built-in flash lamps FL, and a halogen heating part 4 including a plurality of built-in halogen lamps HL. The flash heating part 5 is provided over the chamber 6, and the halogen heating part 4 is provided under the chamber 6. The heat treatment apparatus 1 further includes a holder 7 provided inside the chamber 6 and for holding a semiconductor wafer W in a horizontal attitude, and a transfer mechanism 10 provided inside the chamber 6 and for transferring a semiconductor wafer W between the holder 7 and the outside of the heat treatment apparatus 1. The heat treatment apparatus 1 further includes a controller 3 for controlling operating mechanisms provided in the halogen heating part 4, the flash heating part 5, and the chamber 6 to cause the operating mechanisms to heat-treat a semiconductor wafer W.

The chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the chamber 6 is a disk-shaped member made of quartz, and serves as a quartz window that transmits flashes of light emitted from the flash heating part 5 therethrough into the chamber 6. The lower chamber window 64 forming the floor of the chamber 6 is also a disk-shaped member made of quartz, and serves as a quartz window that transmits light emitted from the halogen heating part 4 therethrough into the chamber 6.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the chamber 6, and surrounds the holder 7 which holds a semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (throat) 66 for the transport of a semiconductor wafer W therethrough into and out of the chamber 6. The transport opening 66 is openable and closable by a gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the chamber 6 is an enclosed space.

The chamber side portion 61 is further provided with a through hole 61a and a through hole 61b both bored therein. The through hole 61a is a cylindrical hole for directing infrared light emitted from an upper surface of a semiconductor wafer W held by a susceptor 74 to be described later therethrough to an upper radiation thermometer 25. The through hole 61b is a cylindrical hole for directing infrared light emitted from a lower surface of the semiconductor wafer W therethrough to a lower radiation thermometer 20. The through holes 61a and 61b are inclined with respect to a horizontal direction so that the longitudinal axes of the respective through holes 61a and 61b intersect main surfaces of the semiconductor wafer W held by the susceptor 74. A transparent window 26 made of calcium fluoride material transparent to infrared light in a wavelength range measurable with the upper radiation thermometer 25 is mounted to an end portion of the through hole 61a which faces the heat treatment space 65. The upper radiation thermometer 25 receives infrared light radiated from the upper surface of the semiconductor wafer W through the transparent window 26, and measures the temperature of the upper surface of the semiconductor wafer W based on the intensity of the infrared light. A transparent window 21 made of barium fluoride material transparent to infrared light in a wavelength range measurable with the lower radiation thermometer 20 is mounted to an end portion of the through hole 61b which faces the heat treatment space 65. The lower radiation thermometer 20 receives infrared light radiated from the lower surface of the semiconductor wafer W through the transparent window 21, and measures the temperature of the lower surface of the semiconductor wafer W based on the intensity of the infrared light.

A gas supply opening 81 for supplying a treatment gas therethrough into the heat treatment space 65 is provided in an upper portion of the inner wall of the chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the chamber 6. The gas supply pipe 83 is connected to a treatment gas supply source 85. A valve 84 is interposed in the gas supply pipe 83. When the valve 84 is opened, the treatment gas is fed from the treatment gas supply source 85 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. The treatment gas supply source 85 can supply, for example, an inert gas such as nitrogen (N₂) and argon (Ar), a reactive gas such as oxygen (O₂), ozone (O₃), and hydrogen (H₂), or a mixed gas thereof, as a treatment gas, into the chamber 6.

A gas exhaust opening 86 for exhausting a gas from the heat treatment space 65 is provided in a lower portion of the inner wall of the chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the chamber 6. The gas exhaust pipe 88 is connected to an exhaust part 190. A valve 89 is interposed in the gas exhaust pipe 88. When the valve 89 is opened, the gas in the heat treatment space 65 is exhausted through the gas exhaust opening 86 and the buffer space 87 to the gas exhaust pipe 88. The gas supply opening 81 and the gas exhaust opening 86 may include a plurality of gas supply openings 81 and a plurality of gas exhaust openings 86, respectively, arranged in a circumferential direction of the chamber 6, and may be in the form of slits.

A gas exhaust pipe 191 for exhausting the gas from the heat treatment space 65 is also connected to a distal end of the transport opening 66. The gas exhaust pipe 191 is connected through a valve 192 to the exhaust part 190. By opening the valve 192, the gas in the chamber 6 is exhausted through the transport opening 66.

The exhaust part 190 includes a vacuum pump. While the exhaust part 190 is caused to operate, the valves 89 and 192 are opened. As a result, the atmosphere in the chamber 6 is discharged from the gas exhaust pipes 88 and 191 to the exhaust part 190. When the atmosphere in the heat treatment space 65 that is an enclosed space is exhausted by the exhaust part 190 without supply of any gas from the gas supply opening 81, the pressure of the chamber 6 can be reduced to a pressure lower than the atmospheric pressure.

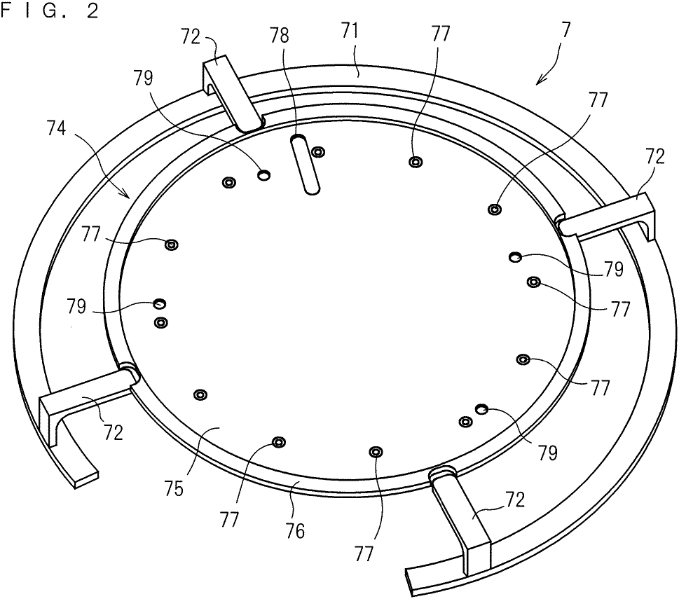

FIG. 2 is a perspective view showing the entire external appearance of the holder 7. The holder 7 includes a base ring 71, coupling portions 72, and the susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the chamber 6 by being placed on the bottom surface of the recessed portion 62 (with reference to FIG. 1). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

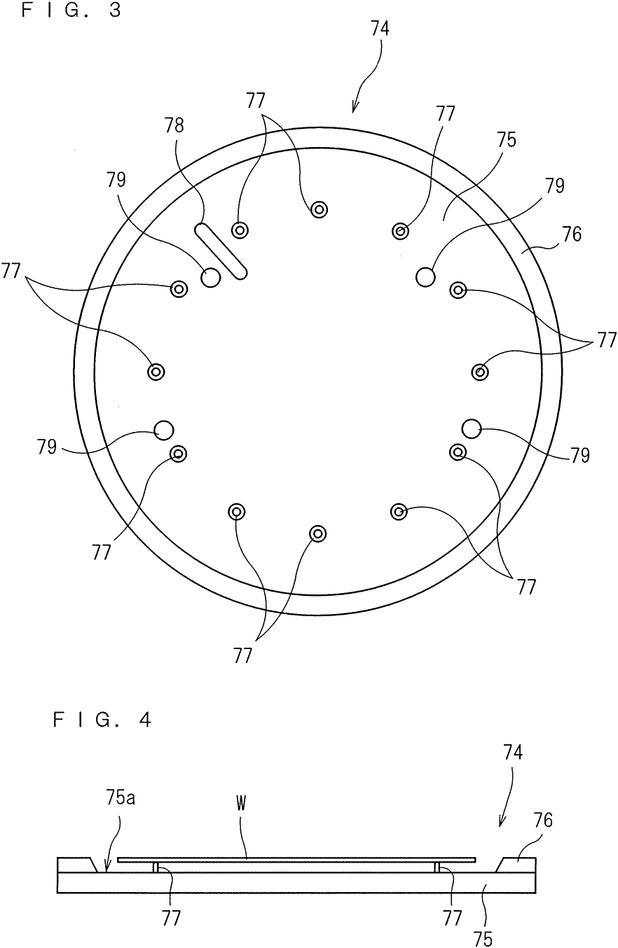

The susceptor 74 is supported by the four coupling portions 72 provided on the base ring 71. FIG. 3 is a plan view of the susceptor 74. FIG. 4 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 are spaced at intervals of 30 degrees along the circumference of a circle concentric with the outer circumference of the holding surface 75a (the inner circumference of the guide ring 76). The diameter of the circle in which the 12 substrate support pins 77 are placed (the distance between the opposing substrate support pins 77) is smaller than the diameter of the semiconductor wafer W. Each of the substrate support pins 77 is made of quartz. The substrate support pins 77 may be provided by welding on the upper surface of the holding plate 75 or machined integrally with the holding plate 75.

Referring again to FIG. 2, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the chamber 6, whereby the holder 7 is mounted to the chamber 6. With the holder 7 mounted to the chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the chamber 6 is placed and held in a horizontal attitude on the susceptor 74 of the holder 7 mounted to the chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W is supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 2 and 3, an opening 78 is provided in the holding plate 75 of the susceptor 74 so as to extend vertically through the holding plate 75 of the susceptor 74. The opening 78 is provided for the lower radiation thermometer 20 to receive radiation (infrared light) emitted from the lower surface of the semiconductor wafer W. Specifically, the lower radiation thermometer 20 receives the radiation emitted from the lower surface of the semiconductor wafer W through the opening 78 and the transparent window 21 mounted to the through hole 61b in the chamber side portion 61 to measure the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer a semiconductor wafer W.

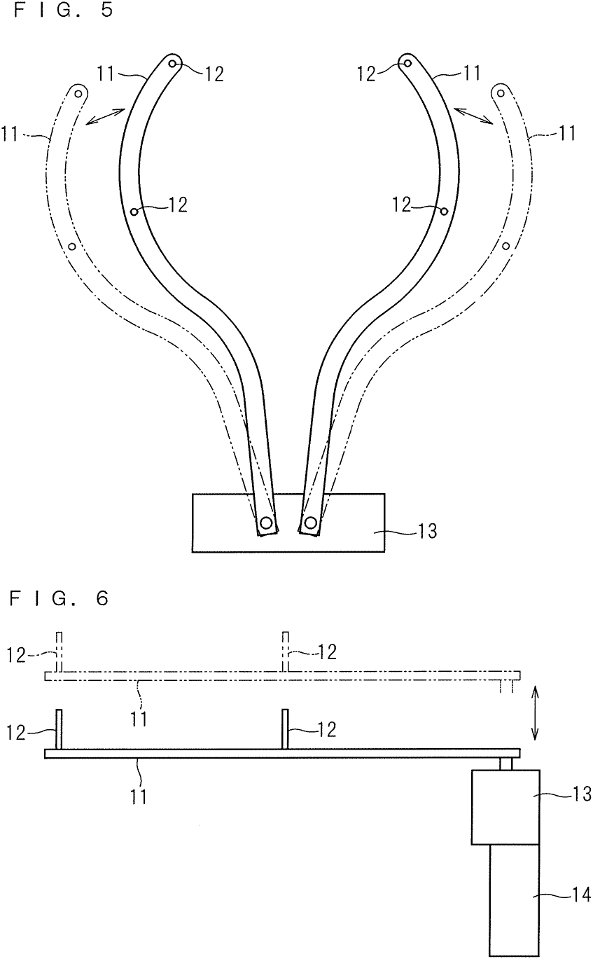

FIG. 5 is a plan view of the transfer mechanism 10. FIG. 6 is a side view of the transfer mechanism 10. The transfer mechanism 10 includes the two transfer arms 11.

The transfer arms 11 are of an arcuate configuration extending substantially along the annular recessed portion 62. Each of the transfer arms 11 includes the two lift pins 12 mounted upright thereon. The transfer arms 11 and the lift pins 12 are made of quartz. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which a semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in plan view. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 2 and 3) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the chamber 6.

Referring back to FIG. 1, the chamber 6 is provided with the two radiation thermometers (pyrometers in the present embodiment) of the lower radiation thermometer 20 and the upper radiation thermometer 25. The lower radiation thermometer 20 is provided obliquely downward with respect to the semiconductor wafer W held by the susceptor 74. The lower radiation thermometer 20 receives infrared light radiated from the lower surface of the semiconductor wafer W, and measures the temperature of the lower surface based on the intensity of the infrared light. Meanwhile, the upper radiation thermometer 25 is provided obliquely upward with respect to the semiconductor wafer W held by the susceptor 74. The upper radiation thermometer 25 receives infrared light radiated from the upper surface of the semiconductor wafer W, and measures the temperature of the upper surface based on the intensity of the infrared light. The upper radiation thermometer 25 includes an optical element of indium antimonide (InSb) to cope with rapid temperature change of the upper surface of the semiconductor wafer W at the instant when flash light is emitted.

The flash heating part 5 provided over the chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash heating part 5 further includes a lamp light radiation window 53 mounted to the bottom of the enclosure 51. The lamp light radiation window 53 forming the floor of the flash heating part 5 is a plate-like quartz window made of quartz. The flash heating part 5 is provided over the chamber 6, whereby the lamp light radiation window 53 is opposed to the upper chamber window 63. The flash lamps FL direct flashes of light from over the chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane. An area in which the plurality of flash lamps FL are arranged is larger than the planar size of the semiconductor wafer W.

Each of the xenon flash lamps FL includes a rod-shaped glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. Such a xenon flash lamp FL has the property of being capable of emitting extremely intense light as compared with a light source that stays lit continuously such as a halogen lamp HL because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen heating part 4 provided under the chamber 6 includes an enclosure 41 incorporating the multiple (in the present preferred embodiment, 40) halogen lamps HL. The halogen heating part 4 directs light from under the chamber 6 through the lower chamber window 64 toward the heat treatment space 65 to heat the semiconductor wafer W by means of the halogen lamps HL.

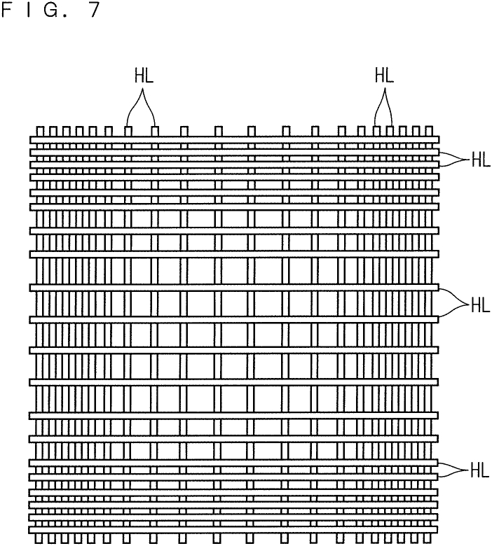

FIG. 7 is a plan view showing an arrangement of the multiple halogen lamps HL. The 40 halogen lamps HL are arranged in two tiers, i.e. upper and lower tiers. That is, 20 halogen lamps HL are arranged in the upper tier closer to the holder 7, and 20 halogen lamps HL are arranged in the lower tier farther from the holder 7 than the upper tier. Each of the halogen lamps HL is a rod-shaped lamp having an elongated cylindrical shape. The 20 halogen lamps HL in each of the upper and lower tiers are arranged so that the longitudinal directions thereof are in parallel with each other along a main surface of a semiconductor wafer W held by the holder 7 (that is, in a horizontal direction). Thus, a plane defined by the arrangement of the halogen lamps HL in each of the upper and lower tiers is also a horizontal plane.

As shown in FIG. 7, the halogen lamps HL in each of the upper and lower tiers are disposed at a higher density in a region opposed to a peripheral portion of the semiconductor wafer W held by the holder 7 than in a region opposed to a central portion thereof. In other words, the halogen lamps HL in each of the upper and lower tiers are arranged at shorter intervals in a peripheral portion of the lamp arrangement than in a central portion thereof. This allows a greater amount of light to impinge upon the peripheral portion of the semiconductor wafer W where a temperature decrease is prone to occur when the semiconductor wafer W is heated by the irradiation thereof with light from the halogen heating part 4.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the 20 halogen lamps HL arranged in the upper tier and the longitudinal direction of the 20 halogen lamps HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. That is, the halogen lamps HL are continuous lighting lamps that emit light continuously for not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen heating part 4 under the halogen lamps HL arranged in two tiers (FIG. 1). The reflector 43 reflects the light emitted from the halogen lamps HL toward the heat treatment space 65.

The controller 3 controls various operating mechanisms provided in the heat treatment apparatus 1. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a magnetic disk for storing control software, data and the like thereon. The CPU in the controller 3 executes a predetermined processing program, whereby the processes in the heat treatment apparatus 1 proceed.

The heat treatment apparatus 1 further includes, in addition to the aforementioned components, various cooling structures to prevent an excessive temperature rise in the halogen heating part 4, the flash heating part 5, and the chamber 6 because of the heat energy generated from the halogen lamps HL and the flash lamps FL during the heat treatment of a semiconductor wafer W. As an example, a water cooling tube (not shown) is provided in the walls of the chamber 6. Also, the halogen heating part 4 and the flash heating part 5 have an air cooling structure for forming a gas flow therein to exhaust heat. Air is supplied to a gap between the upper chamber window 63 and the lamp light radiation window 53 to cool down the flash heating part 5 and the upper chamber window 63.

Next, a procedure for treatment of the semiconductor wafer W in the heat treatment apparatus 1 will be described. Here, the semiconductor wafer W as an object being treated is a semiconductor substrate doped with impurities (ions) by an ion implantation process. The impurities are activated by flash-light irradiation heating treatment (annealing) performed by the heat treatment apparatus 1. The procedure for treatment in the heat treatment apparatus 1 described below proceeds under the control of the controller 3 over operating mechanisms of the heat treatment apparatus 1.

Prior to the treatment of the semiconductor wafer W, the valve 84 for supply of gas is opened, and the valve 89 for exhaust of gas is opened, so that the supply and exhaust of gas into and out of the chamber 6 start. When the valve 84 is opened, nitrogen gas is supplied through the gas supply opening 81 into the heat treatment space 65. When the valve 89 is opened, the gas within the chamber 6 is exhausted through the gas exhaust opening 86. This causes the nitrogen gas supplied from an upper portion of the heat treatment space 65 in the chamber 6 to flow downwardly and then to be exhausted from a lower portion of the heat treatment space 65.

The gas within the chamber 6 is exhausted also through the transport opening 66 by opening the valve 192. Further, the exhaust mechanism not shown exhausts an atmosphere near the drivers of the transfer mechanism 10. It should be noted that the nitrogen gas is continuously supplied into the heat treatment space 65 during the heat treatment of a semiconductor wafer W in the heat treatment apparatus 1. The amount of nitrogen gas supplied into the heat treatment space 65 is changed as appropriate in accordance with process steps.

Subsequently, the gate valve 185 is opened to open the transport opening 66. A transport robot outside the heat treatment apparatus 1 transports a semiconductor wafer W to be treated through the transport opening 66 into the heat treatment space 65 of the chamber 6. At this time, there is a danger that an atmosphere outside the heat treatment apparatus 1 is carried into the heat treatment space 65 as the semiconductor wafer W is transported into the heat treatment space 65. However, the nitrogen gas is continuously supplied into the chamber 6. Thus, the nitrogen gas flows outwardly through the transport opening 66 to minimize the outside atmosphere carried into the heat treatment space 65.

The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the semiconductor wafer W is placed on the lift pins 12, the transport robot moves out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. Further, the semiconductor wafer W is held by the holder 7 such that the front surface thereof having been patterned and implanted with impurities faces upward. A predetermined distance is defined between a back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is held from below in a horizontal attitude by the susceptor 74 of the holder 7 made of quartz, the 40 halogen lamps HL in the halogen heating part 4 turn on simultaneously to start preheating (or assist-heating). Halogen light emitted from the halogen lamps HL is transmitted through the lower chamber window 64 and the susceptor 74 both made of quartz, and impinges upon the lower surface of the semiconductor wafer W. By receiving light irradiation from the halogen lamps HL, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

The temperature of the semiconductor wafer W which is on the increase by the irradiation with light from the halogen lamps HL is measured by the lower radiation thermometer 20. The measured temperature of the semiconductor wafer W is transmitted to the controller 3. The controller 3 controls the output from the halogen lamps HL while monitoring whether the temperature of the semiconductor wafer W which is on the increase by the irradiation with light from the halogen lamps HL reaches a predetermined preheating temperature T1 or not. In other words, the controller 3 effects feedback control of the output from the halogen lamps HL so that the temperature of the semiconductor wafer W is equal to the preheating temperature T1, based on the value measured by the lower radiation thermometer 20. The preheating temperature T1 is about 200° C. to 800° C. at which the impurities doped into the semiconductor wafer W would not be diffused by heat, and is preferably about 350° C. to 600° C. (600° C. in the present embodiment).

After the temperature of the semiconductor wafer W reaches the preheating temperature T1, the controller 3 maintains the temperature of the semiconductor wafer W at the preheating temperature T1 for a short time. Specifically, at the point in time when the temperature of the semiconductor wafer W measured by the lower radiation thermometer 20 reaches the preheating temperature T1, the controller 3 adjusts the output from the halogen lamps HL to maintain the temperature of the semiconductor wafer W at approximately the preheating temperature T1.

By performing such preheating using the halogen lamps HL, the temperature of the entire semiconductor wafer W is uniformly increased to the preheating temperature T1. In the stage of preheating using the halogen lamps HL, the semiconductor wafer W shows a tendency to be lower in temperature in a peripheral portion thereof where heat dissipation is liable to occur than in a central portion thereof. However, the halogen lamps HL in the halogen heating part 4 are disposed at a higher density in the region opposed to the peripheral portion of the semiconductor wafer W than in the region opposed to the central portion thereof. This causes a greater amount of light to impinge upon the peripheral portion of the semiconductor wafer W where heat dissipation is liable to occur, thereby providing a uniform in-plane temperature distribution of the semiconductor wafer W in the stage of preheating.

The flash lamps FL in the flash heating part 5 irradiate the front surface of the semiconductor wafer W held by the susceptor 74 with a flash of light at the point in time when a predetermined time period has elapsed since the temperature of the semiconductor wafer W reached the preheating temperature T1. At this time, part of the flash of light emitted from the flash lamps FL travels directly toward the interior of the chamber 6. The remainder of the flash of light is reflected once from the reflector 52, and then travels toward the interior of the chamber 6. The irradiation of the semiconductor wafer W with such flashes of light achieves the flash heating of the semiconductor wafer W.

The flash heating, which is achieved by the emission of a flash of light from the flash lamps FL, is capable of increasing the front surface temperature of the semiconductor wafer W in a short time. Specifically, the flash of light emitted from the flash lamps FL is an intense flash of light emitted for an extremely short period of time ranging from about 0.1 to about 100 milliseconds (both inclusive) as a result of the conversion of the electrostatic energy previously stored in the capacitor into such an ultrashort light pulse. Then, the temperature of the front surface of the semiconductor wafer W subjected to flash heating through irradiation with flash light from the flash lamps FL instantaneously rises to a treatment temperature T2 of 1000° C. or higher, and the temperature of the front surface rapidly decreases after the impurities implanted into the semiconductor wafer W are activated. As described above, the heat treatment apparatus 1 can raise and lower the temperature of the front surface of the semiconductor wafer W in an extremely short time, and hence can activate impurities while suppressing thermal diffusion of the impurities implanted into the semiconductor wafer W. A period of time required for activation of impurities is much shorter than a period of time required for thermal diffusion thereof. Thus, activation is completed in such a short period of time as about 0.1 millisecond to 100 milliseconds in which diffusion would not occur.

After a predetermined time period has elapsed since the completion of the flash heating treatment, the halogen lamps HL turn off. This causes the temperature of the semiconductor wafer W to decrease rapidly from the preheating temperature T1. The lower radiation thermometer 20 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement by means of the lower radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport robot outside the heat treatment apparatus 1 transports the semiconductor wafer W placed on the lift pins 12 out of the chamber 6. Thus, the heating treatment of the semiconductor wafer W in the heat treatment apparatus 1 is completed.

Meanwhile, when the flash lamps FL emit flash light, the temperature of the front surface of the semiconductor wafer W instantaneously rises to the treatment temperature T2 of 1000° C. or higher, whereas the temperature of the back surface at that moment does not significantly rise from the preheating temperature T1. That is, there instantaneously occurs a temperature difference between the upper surface and the lower surface of the semiconductor wafer W. As a result, only the front surface of the semiconductor wafer W abruptly thermally expands, and the back surface hardly thermally expands. Thus, the semiconductor wafer W is instantaneously warped in such a manner that its upper surface becomes convex. At that time, the semiconductor wafer W is likely to be cracked. In a case in which the semiconductor wafer W has a scratch in particular, the probability of cracking is high.

The inventors of the present application have conducted intensive studies, and found that varying the setting positions of the plurality of substrate support pins 77 on the susceptor 74 according to the pulse width of flash light emitted from the flash lamps FL can reduce cracking of the semiconductor wafer W. The present invention has been completed based on the above-described findings. As the pulse width of flash light decreases, the radius of the setting circle in which the plurality of substrate support pins 77 are set is made larger.

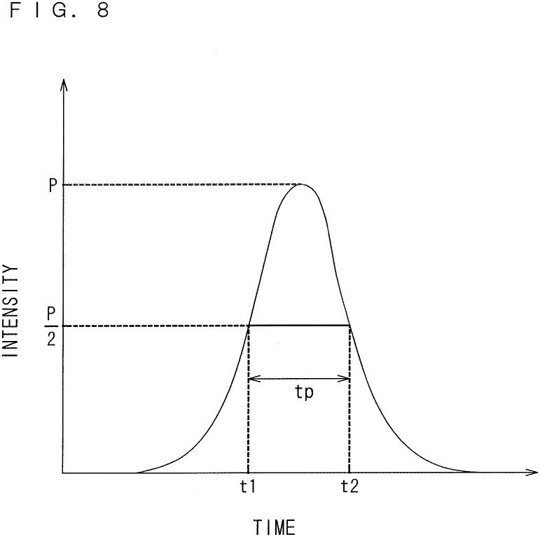

FIG. 8 is a view for explaining the pulse width of flash light emitted from the flash lamps FL. Typically, when the flash lamps FL emit flash light once, a change in the intensity of the flash light is a pulse as shown in FIG. 8. In the pulse in FIG. 8, the intensity at the peak is the highest intensity P. The terms “pulse width” mean a half-width of a pulse. Specifically, in FIG. 8, a period of time tp from a time t1 when the intensity of the pulse becomes equal to a half (P/2) of the highest intensity P in the course of increasing, to a time t2 when the intensity of the pulse becomes equal to a half of the highest intensity P in the course of decreasing, is a pulse width.

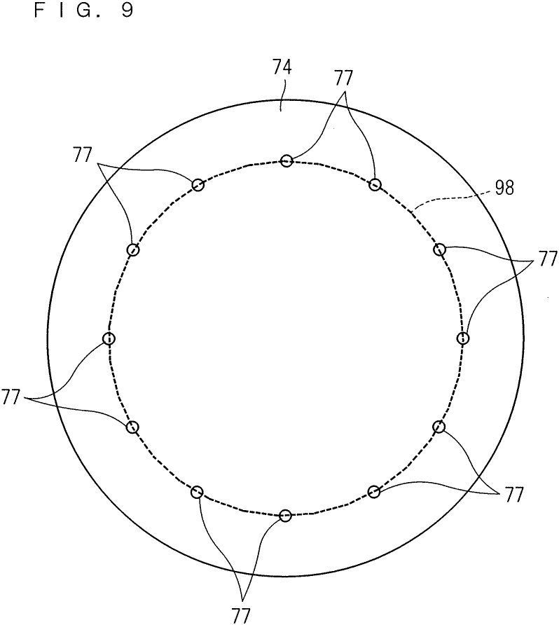

FIG. 9 is a view for explaining a setting circle in which the substrate support pins 77 are set. As described above, in the present embodiment, the 12 substrate support pins 77 are set every 30° in a ring shape on the susceptor 74. A circle formed by the plurality of substrate support pins 77 set in a ring shape is a setting circle 98. The setting circle 98 has a radius smaller than the radius of the semiconductor wafer W as a matter of course. Specifically, when the semiconductor wafer W has a diameter of 300 mm, the setting circle 98 has a radius of 150 mm or less.

FIG. 10 is a view showing a correlation between a pulse width and the radius of the setting circle 98, by which cracking of the semiconductor wafer W can be reduced. As shown in the drawing, by increasing the radius of the setting circle 98 as the pulse width of flash light emitted from the flash lamps FL decreases, it is possible to reduce cracking of the semiconductor wafer W. The pulse width of flash light emitted from the flash lamps FL is defined in a recipe. The recipe defines a treatment procedure and treatment conditions of the semiconductor wafer W. Thus, when a pulse width defined in the recipe is short, it is possible to reduce cracking of the semiconductor wafer W during flash-light irradiation by using the susceptor 74 with the setting circle 98 having a large radius in which the plurality of substrate support pins 77 are set.

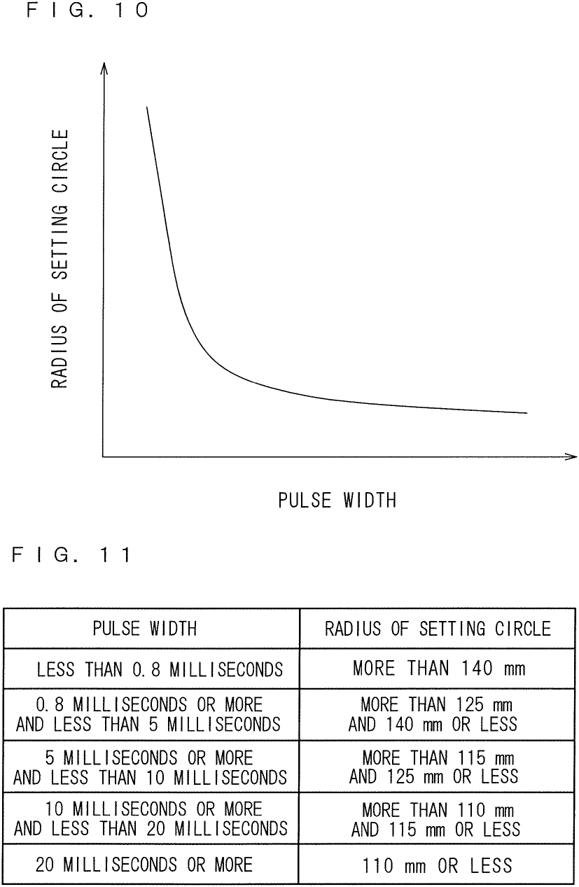

FIG. 11 is a view showing a more specific correspondence between a pulse width and a radius of the setting circle 98, by which cracking of the semiconductor wafer W can be reduced. It is presupposed that the semiconductor wafer W has a diameter of 300 mm. When the pulse width of flash light emitted from the flash lamps FL is less than 0.8 milliseconds, it is possible to reduce cracking of the semiconductor wafer W during flash-light irradiation by making the radius of the setting circle 98 larger than 140 mm (in other words, by making the radius of the setting circle 98 larger than 93% of the radius of the semiconductor wafer W). Note that the upper limit of the radius of the setting circle 98 is 150 mm.

Further, when the pulse width is equal to or more than 0.8 milliseconds and is less than 5 milliseconds, it is possible to reduce cracking of the semiconductor wafer W by making the radius of the setting circle 98 larger than 125 mm and equal to or smaller than 140 mm (in other words, by making the radius of the setting circle 98 larger than 83% of the radius of the semiconductor wafer W and equal to or smaller than 93%). When the pulse width is equal to or more than 5 milliseconds and is less than 10 milliseconds, it is possible to reduce cracking of the semiconductor wafer W by making the radius of the setting circle 98 larger than 115 mm and equal to or smaller than 125 mm (in other words, by making the radius of the setting circle 98 larger than 77% of the radius of the semiconductor wafer W and equal to or smaller than 83%). When the pulse width is equal to or more than 10 milliseconds and is less than 20 milliseconds, it is possible to reduce cracking of the semiconductor wafer W by making the radius of the setting circle 98 larger than 110 mm and equal to or smaller than 115 mm (in other words, by making the radius of the setting circle 98 larger than 73% of the radius of the semiconductor wafer W and equal to or smaller than 77%). Furthermore, when the pulse width is equal to or more than 20 milliseconds, it is possible to reduce cracking of the semiconductor wafer W by making the radius of the setting circle 98 equal to or smaller than 110 mm (in other words, by making the radius of the setting circle 98 equal to or smaller than 73% of the radius of the semiconductor wafer W).

The semiconductor wafer W is held by the susceptor 74 in which the plurality of substrate support pins 77 are arranged along the setting circle 98 having a radius as shown in FIG. 11. This can prevent cracking of the semiconductor wafer W despite of possible instantaneous warp of the semiconductor wafer W during flash-light irradiation.

In the first embodiment, the radius of the setting circle 98 in which the plurality of substrate support pins 77 are set is made larger as the pulse width of flash light emitted from the flash lamps FL decreases. To irradiate the semiconductor wafer W with flash light from the flash lamps FL while having the semiconductor wafer W supported by the plurality of substrate support pins 77 can prevent cracking of the semiconductor wafer W despite possible abrupt deformation of the semiconductor wafer W due to the flash-light irradiation.

### Second Embodiment

Next, a second embodiment of the present invention will be described. An overall configuration of the heat treatment apparatus 1 according to the second embodiment is the same as that according to the first embodiment. A procedure for treating the semiconductor wafer W according to the second preferred embodiment is also similar to that according to the first embodiment. The second embodiment is different from the first embodiment in a structure including the susceptor 74 and the plurality of substrate support pins 77.

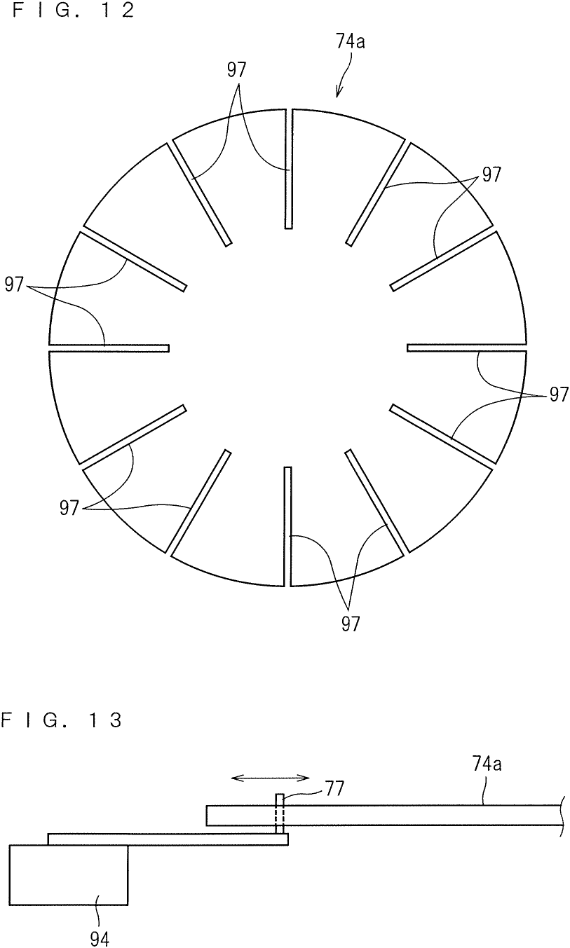

FIG. 12 is a plan view of a susceptor 74a according to the second embodiment. The overall shape and material of the susceptor 74a are the same as those of the susceptor 74 of the first embodiment. The susceptor 74a of the second embodiment is provided with 12 slits 97. The 12 slits 97 are provided at equal intervals of 30°. Each of the 12 slits 97 is formed so as to extend from the outer edge toward the center of the susceptor 74a substantially in a disk shape, along the radial direction of the susceptor 74a. Each of the slits 97 has a width smaller than 8 mm and larger than the width of the substrate support pin 77. Further, each of the slits 97 can have an appropriate length, but preferably has a length of 50 mm or larger.

FIG. 13 is a view showing a manner in which the substrate support pin 77 is caused to slide over the slit 97 of the susceptor 74a. In the second embodiment, the 12 substrate support pins 77 are movably provided. Each of the 12 substrate support pins 77 is caused to slide back and forth along the slit 97 by a pin moving mechanism 94. The slit 97 is provided along the radius direction of the susceptor 74a, and hence also the substrate support pin 77 is moved along the radial direction of the susceptor 74a. The upper end of the substrate support pin 77 protrudes upward from the upper surface of the susceptor 74a.

The positions of the substrate support pins 77 in the second embodiment are similar to those in the first embodiment. That is, the pin moving mechanism 94 moves the positions of the substrate support pins 77 such that the radius of the setting circle 98 in which the plurality of substrate support pins 77 are set increases as the pulse width of flash light emitted from the flash lamps FL decreases. More specifically, the substrate support pins 77 are moved such that the pulse width of flash light and the radius of the setting circle 98 have a correlation as shown in FIG. 11. The pin moving mechanism 94 may move the plurality of substrate support pins 77 such that the setting circle 98 has a radius as shown in FIG. 11 based on the pulse width defined in the recipe, under control of the controller 3.

In the second embodiment, while the plurality of substrate support pins 77 are formed so as to be movable, the radius of the setting circle 98 in which the plurality of substrate support pins 77 are set is made larger as the pulse width of flash light emitted from the flash lamps FL decreases. Therefore, in the same manner as in the first embodiment, to irradiate the semiconductor wafer W with flash light while having the wafer supported by the plurality of substrate support pins 77 can prevent cracking of the semiconductor wafer W despite possible abrupt deformation of the semiconductor wafer W due to the flash-light irradiation.

### Modification

While the preferred embodiment according to the present invention has been described hereinabove, various modifications of the present invention in addition to those described above may be made without departing from the scope and spirit of the invention. For example, the susceptor 74 is provided with the 12 substrate support pins 77 in the above-described embodiments, but the present invention is not limited thereto. It is only required that the number of substrate support pins 77 is three or more, and the number of substrate support pins 77 may be four or eight. In the second embodiment, the same number of slits 97 as the substrate support pins 77 are provided in the susceptor 74a.

Although the 30 flash lamps FL are provided in the flash heating part 5 according to the aforementioned preferred embodiment, the present invention is not limited to this. Any number of flash lamps FL may be provided. The flash lamps FL are not limited to the xenon flash lamps, but may be krypton flash lamps. Also, the number of halogen lamps HL provided in the halogen heating part 4 is not limited to 40. Any number of halogen lamps HL may be provided.

In the aforementioned preferred embodiment, the filament-type halogen lamps HL are used as continuous lighting lamps that emit light continuously for not less than one second to perform preheating the semiconductor wafer W. The present invention, however, is not limited to this. In place of the halogen lamps HL, discharge type arc lamps (e.g., xenon arc lamps) or LED lamps may be used as the continuous lighting lamps to perform preheating.

EXPLANATION OF REFERENCE SIGNS

| | |
|---|---|
| 1: | heat treatment apparatus |
| 3: | controller |
| 4: | halogen heating unit |
| 5: | flash heating unit |
| 6: | chamber |
| 7: | holder |
| 10: | transfer mechanism |
| 65: | heat treatment space |
| 74, 74a: | susceptor |
| 75: | holding plate |
| 77: | substrate support pin |
| 94: | pin moving mechanism |
| 97: | slit |
| 98: | setting circle |
| FL: | flash lamp |
| HL: | halogen lamp |
| W: | semiconductor wafer |

1. A heat treatment apparatus that irradiates a substrate with flash light to heat the substrate, comprising:
a chamber that accommodates a substrate;
a susceptor that holds said substrate in said chamber; and
a plurality of support pins provided on said susceptor to support said substrate; and
a flash lamp that irradiates said substrate held by said susceptor with flash light, wherein
positions where said plurality of support pins are set on said susceptor differ according to a pulse width of flash light emitted from said flash lamp.

2. The heat treatment apparatus according to claim 1, wherein
said plurality of support pins are set in a ring shape on said susceptor, and
a radius of a setting circle in which said plurality of support pins are set increases as said pulse width decreases.

3. The heat treatment apparatus according to claim 2, wherein
when said pulse width is less than 0.8 milliseconds, the radius of said setting circle is larger than 93% of a radius of said substrate,
when said pulse width is equal to or more than 0.8 milliseconds and is less than 5 milliseconds, the radius of said setting circle is larger than 83% of the radius of said substrate and is equal to or smaller than 93% of the radius of said substrate,
when said pulse width is equal to or more than 5 milliseconds and is less than 10 milliseconds, the radius of said setting circle is larger than 77% of the radius of said substrate and is equal to or smaller than 83% of the radius of said substrate,
when said pulse width is equal to or more than 10 milliseconds and is less than 20 milliseconds, the radius of said setting circle is larger than 73% of the radius of said substrate and is equal to or smaller than 77% of the radius of said substrate, and
when said pulse width is equal to or more than 20 milliseconds, the radius of said setting circle is equal to or smaller than 73% of the radius of said substrate.

4. The heat treatment apparatus according to claim 1, further comprising a pin moving mechanism that changes the positions of said plurality of support pins in accordance with said pulse width.

5. The heat treatment apparatus according to claim 4, wherein
a plurality of slits are formed along a radial direction in said susceptor, and
said pin moving mechanism slides said plurality of support pins along said plurality of slits.
